(19) United States
(12) Patent Application Publication
(10) Pub. No.: US 2010/0230155 A1
(43) Pub. Date: Sep. 16, 2010

(54) APPARATUS COMPRISING AN ELECTRONICS MODULE AND METHOD OF ASSEMBLING APPARATUS

(75) Inventors: Kenichi Hashizume, Gunma (JP); Hideki Ohhashi, Helsinki (FI); Esa-Sakari Määttä, Farnborough (GB)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/529,400

(22) PCT Filed: Mar. 1, 2009
(86) PCT No.: PCT/IB07/00595

§ 371 Date: Jun. 1, 2010

(51) Int. Cl. H01L 23/28; B29C 45/14

(52) U.S. Cl. 174/521; 264/272.14

(57) ABSTRACT

An apparatus comprising: a substrate; an electronics module mounted on the substrate; and an injection molded layer in contact with the substrate; wherein the substrate and the injection molded layer form a portion of a rigid housing.

### FIELD OF THE INVENTION

Embodiments of the present invention relate to an apparatus comprising an electronics module and a method of assembling such an apparatus. In particular they relate to an apparatus comprising an electronics module and an injection molded layer.

### BACKGROUND TO THE INVENTION

In recent years there has been a trend to reduce the thickness of electronic devices. Problems arise during the formation of the housings of thin electronic devices. The housings are commonly formed by injection molding and the conditions required for injection molding, i.e. the high temperature of the material and the force with which the injection molded material enters the mold, may damage sensitive electronic modules.

The housings may be formed from attachable covers which are formed independently of the electronics modules and components of the device and thereby avoid damaging the electronics during injection molding. Such housings define a cavity for receiving the electronics modules and components. However, the cavity must be slightly oversized so that manufacturing tolerances do not result in a cavity that ‘pinches’ the modules and components. The housing also requires means for connecting the housing to the electronics modules and components which increase the volume of the device.

It would be desirable to enable assembly of an electronic device without damaging the electronic modules and without significantly increasing the thickness of the device.

### BRIEF DESCRIPTION OF THE INVENTION

According to one embodiment of the invention there is provided an apparatus comprising: a substrate; an electronics module mounted on the substrate; and an injection molded layer in contact with the substrate; wherein the substrate and the injection molded layer form a portion of a rigid housing.

This provides an advantage in that the substrate acts as a barrier to protect the electronics module during the formation of the injection molded layer so that the electronics module can be directly connected to the rigid housing. This reduces the number of components required and the number of connections between the components and thereby reduces the thickness of the apparatus.

According to another embodiment of the invention there is provided a method of assembling an apparatus comprising electronic components, the method comprising: positioning a substrate, supporting an electronics module, between the electronics module and a cavity to operate as a barrier during injection molding; forming an injection molded layer in contact with the substrate and thereby integrating the injection molded layer and the substrate to form a portion of a rigid housing.

### BRIEF DESCRIPTION OF THE DRAWINGS

For a better understanding of the present invention reference will now be made by way of example only to the accompanying drawings in which:

FIGS. 1A to D illustrate a method of assembling an apparatus according to an embodiment of the invention;

FIG. 2 is a cross section of an apparatus according to a second embodiment of the invention;

FIGS. 3A to B illustrate a substrate according to an embodiment of the invention;

FIGS. 4A to C illustrate a substrate according to a second embodiment of the invention; and

FIG. 5 illustrates a method of manufacturing the substrate according to an embodiment of the invention.

### DETAILED DESCRIPTION OF EMBODIMENTS OF THE INVENTION

The Figures illustrate an apparatus 1 comprising: a substrate 15; an electronics module 13 mounted on the substrate 15; and an injection molded layer 27 in contact with the substrate 15; wherein the substrate 15 and the injection molded layer 27 form a portion of a rigid housing.

The apparatus 1 may be a hand portable electronic device such as, for example, a portable radiotelephone, a personal digital assistant, a digital camera, a personal media player, etc.

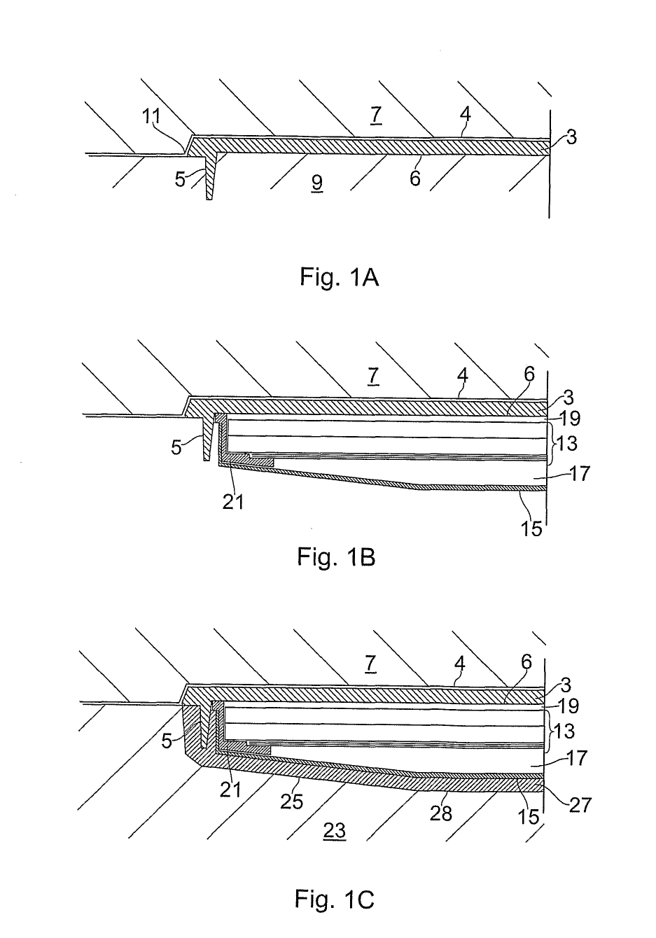

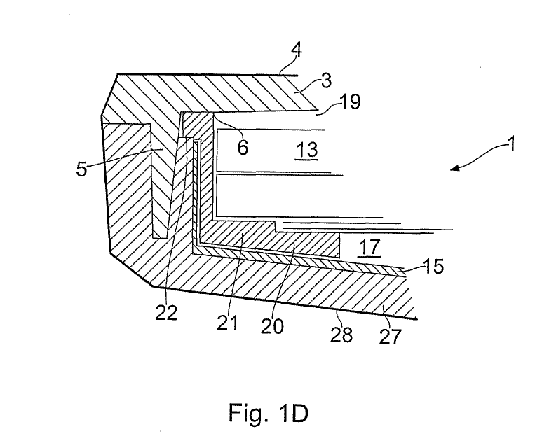

FIGS. 1A to D illustrate a method of assembling the apparatus 1.

FIG. 1A is a cross section through part of a display window 3. The display window 3 comprises a first exterior surface 4 and a second interior surface 6. The display window 3 forms part of a rigid housing. The rigid housing may be the external housing of the apparatus 1 in which case the first exterior surface 4 forms part of the exterior surface of the apparatus 1.

A ridge 5 extends around the perimeter of second interior surface 6 of the display window 3. In some embodiments the ridge 5 may extend around the entire of the perimeter of the display window 3 whilst in other embodiments the ridge 5 may extend around only a portion or portions of the perimeter.

The display window 3 is formed from a transparent material such as a plastic. In the illustrated embodiment the display window 3 is formed by injection molding. The two sides of the mold 7 and 9 form a cavity 11 into which molten plastic is injected. The plastic cools to form the display window 3.

In the second step of the process, illustrated in FIG. 1B, the display window 3 is left in the first part of the mold 7 and the second part of the mold 9 is removed. The display window 3 remains in the cavity 11 and a display module 13, mounted on a substrate 15, is positioned adjacent to the second interior surface 6 of the display window 3.

In the illustrated embodiment the display module 13 is mounted on the substrate by means of an intervening frame 21 so that the display module 13 does not directly contact the substrate 15. The frame 21 is provided around the perimeter of the display module 13 and may be made of any suitable material such as plastic. The frame 21 is adhered to the display module 13 and the substrate 15 and contacts the second interior surface 6 of the display window 3 so as to create a gap 19 between the display window 3 and the display module 13. In this particular embodiment the gap 19 is an air gap.

In other embodiments the display module 13 may be mounted directly on to the substrate 15, in which case the substrate 15 may contact the second interior surface 6 of the display window 3, to provide the gap 19.

In the illustrated embodiment the display module 13 is located within the volume defined by the ridge 5. The ridge 5 provides a guide structure to assist in the positioning of the display module 13.

In the illustrated embodiment the substrate 15 is curved so that a gap 17 is formed between the substrate 15 and the display module 13. In this particular embodiment the gap 17 is an air gap.

The display module 13 may comprise any suitable type of display for example an LCD display or a polymer display.

In FIG. 1C a third mold 23 is positioned next to the mold 7 to form a cavity 25 between the third mold 23 and the ridge 5 of the display window 3 and between the third mold 23 and the substrate 15. An injection molded layer 27 is formed within the cavity 25 around the substrate 15 and ridge 5 of the display window 3. The injection molded layer 27 may be formed from any suitable material such as plastic.

The substrate 15 acts as a protective barrier that prevents the injected molding material directly contacting the display module 13. The injection molded layer 27 forms adjacent to and in contact with the substrate 15 so that the injection molded layer 27 and the substrate 15 are integrated to form at least a portion of a rigid housing for protecting the display module 13.

The rigid housing may form part of the exterior housing of the apparatus 1, in which case the outer surface 28 of the injection molded layer 27 forms part of the exterior surface of the apparatus 1.

When the plastics material is injected into the cavity 25 the gap 17 between the substrate 15 and the display module 13 protects the display module 13 from the heat and force of the injected plastic. For example, the substrate 15 may absorb the force of the plastic being injected into the cavity 25. In some embodiments the substrate 15 may deform under the force of the injection molding, however the gap 17 prevents the deformed substrate 15 from coming into contact with the display module 13. In the illustrated embodiment the gap 19 is an air gap which also insulates the display module 13 against the heat of the injected plastic.

FIG. 1D illustrates the frame 21 around the edge of the display module 13 in more detail. The frame 21 comprises a first portion 20, positioned between the substrate 15 and the display module 13, for mounting the display module 13 onto the substrate 15. The first portion 20 extends substantially parallel to a plane of the display window 3 and has a surface that contacts the substrate 15 that has a curvature that conforms to the curvature of the substrate 15. The display module 13 and the substrate 15 may be treated, for example by etching or a polymer coating, so as to ensure good adhesion to the frame 21.

The frame 21 comprises a second portion 22 which forms a continuous, uninterrupted rim around the edge of the substrate 15 and extends substantially perpendicularly to and abuts the second interior surface 6 of the display window 3.

During formation of the injection molded layer 27 the force of the plastic being injected into the cavity 25 causes the second portion 22 of the frame 21 to be pressed against the second interior surface 6 of the display window 3. This creates a seal with the display window 3 around the edge of the display module 13 and protects the display module 13 by preventing the molten plastic from coming into direct contact with it.

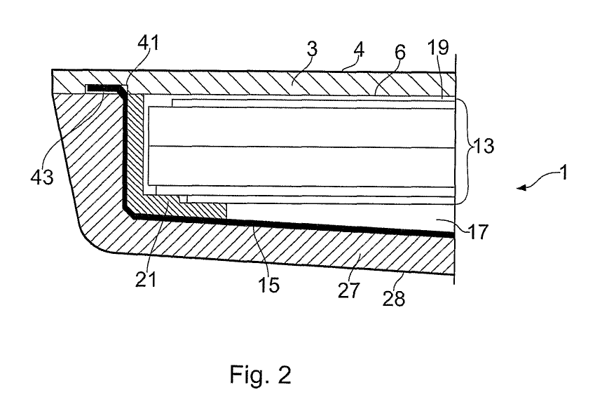

FIG. 2 illustrates a cross section through a part of the apparatus 1 according to a second embodiment of the invention. This embodiment differs from the previous embodiment in that the display window 3 is provided with a recess 41 in the second interior surface 6 to assist in the positioning of the display module 13 instead of a ridge 5. The recess 41 may extend around the entire perimeter of the display window 3.

In this embodiment the substrate 15 is provided with a rim 43 which can be located within the recess 41. The rim 43 extends continuously around the edge of the substrate 15. During formation of the injection molded layer 27 the force of the hot plastic being injected into the cavity 25 presses the rim 43 into the recess 41 to form a seal. The substrate 15 prevents molten plastic from coming into direct contact with the display module 13.

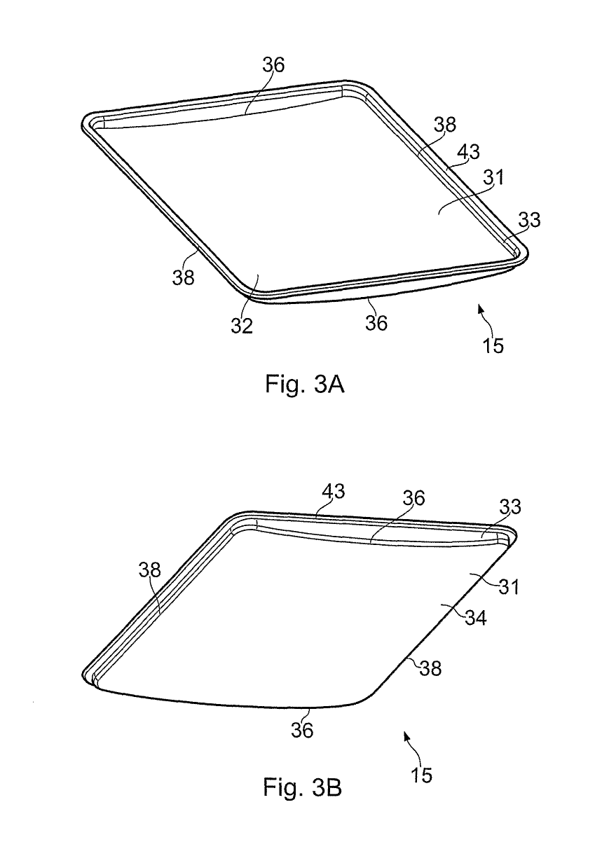

FIGS. 3A and 3B are perspective views of the substrate 15 of an embodiment of the invention without the display module 13 attached. FIG. 3A is a perspective view of the upper side of the substrate 15 and FIG. 3B is a perspective view of the lower side of the substrate 15. With reference to the previously described embodiments, the display module 13 is mounted on the upper side of the substrate 15 and the lower side contacts the injection molded layer 27.

The substrate 15 comprises a body portion 31, having an inner surface 32, an outer surface 34 and edges 36, 38 defining the perimeter of the body portion 31. The substrate 15 also comprises a sidewall 33. The sidewall 33 extends around the perimeter of the body portion 31. In the illustrated embodiment the sidewall 33 extends continuously around the entire perimeter of the body portion 31.

The frame 21 may be adhered to the sidewall 33 to enable the display module 13 to be mounted on to the substrate 15. In alternative embodiments the display module 13 may be adhered directly onto the sidewall 33.

In the illustrated embodiment the sidewall 33 comprises a rim 43 for cooperating with a corresponding recess 41 in the second interior surface 6 of the display window 3. The rim 43 extends continuously around the perimeter of the body portion 31 and may also form a protective seal during the formation of the injection molded layer 27.

In other embodiments there may be no rim 43 around the sidewall 33 of the substrate 15, for example, in embodiments where the interior surface 6 of the display window 3 is provided with a ridge 5.

The body portion 31 is curved so that the inner surface 32 and the outer surface 34 are both curved. In the embodiments illustrated the curvature is in one dimension only. In the illustrated embodiment the substrate 15 is rectangular so that a first two parallel edges 36 are shorter than the other two parallel edges 38. The body portion 31 curves along the width of the body portion 31 but not the length. Therefore the sidewall 33 has a constant depth along the longer edges 38 of the body portion 31 so that when either the frame 21 or the electronics module 13 is mounted on the substrate 15 the inner surface 32 of the body portion 31 is in contact with either the frame 21 or the electronics module 13 along the longer edges 38. Along the shorter edges 36, the depth of the side wall 33 varies so that sidewall 33 is deeper in the middle than at the edges 38 so that when an electronics module 13 is mounted on the substrate 15 inner surface 32 will not contact the electronics module 13 except at the longer edges 38, thus a gap is created between the electronics module 13 and the substrate 15.

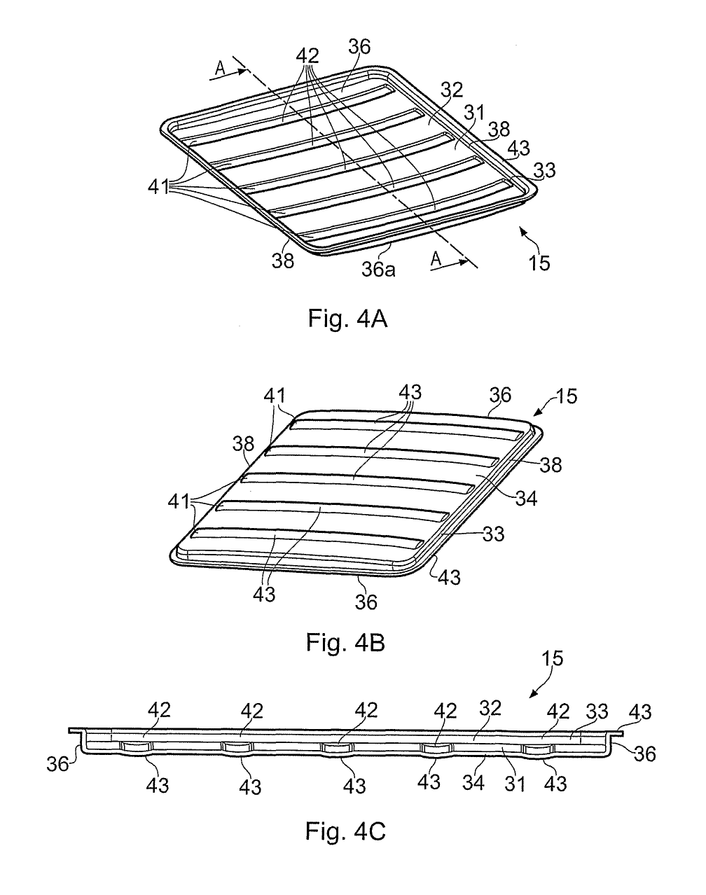

FIGS. 4A and 4B are perspective views of the substrate 15 of a further embodiment of the invention without the display module 13 attached. FIG. 4A is a perspective view of the upper side of the substrate 15, to which the display module 13 can be mounted, and FIG. 4B is a perspective view of the lower side of the substrate 15, which contacts the injection molded layer 27. FIG. 4C is a cross section through the line AA in FIG. 4A.

In this embodiment the body portion 31 of the substrate 15 is provided with a plurality of corrugations 41 which extend in parallel across the width of the body portion 31. In this particular embodiment the corrugations 41 are provided as grooves 42 on the inner surface 32 of the body portion 31 and ridges 43 on the outer surface 34.

The corrugations 41 increase the rigidity of the substrate 15 so that the substrate is less susceptible to deformation during the formation of the injection molded layer 27. This allows the radius of curvature of the substrate 15 to be reduced which also reduces the width of the gap 17 between the substrate 15 and the display module 13 thereby reducing the overall thickness of the apparatus 1.

The substrate 15 may be made of any suitable material. For example, in one embodiment the substrate 15 may be made of a plastic sheet or film. In other embodiments the substrate 15 may be made of metal. Where the substrate 15 is made of metal the substrate 15 may be treated so as to ensure a good adhesion between the substrate 15 and the frame 21 and the injection molded layer 27.

In embodiments where the substrate 15 is made of a plastics material the substrate 15 may be provided with conductive traces for connection to an electronics module. In some embodiments the substrate 15 may be a multilayered PCB or may have electronics components embedded within it. This reduces the amount of wiring and connections needed within the apparatus 1 and thereby reduces the volume of the apparatus 1.

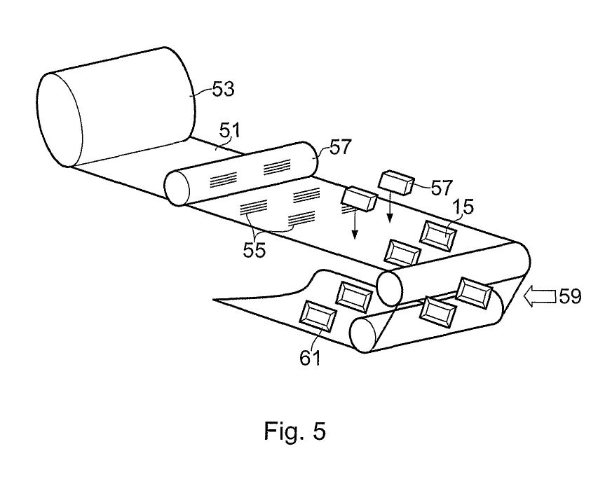

FIG. 5 illustrates a method of manufacturing a substrate 15 having conductive traces printed on it according to an embodiment of the invention.

A plastics sheet 51 is fed through a first roller 53. The plastic sheet 51 may be formed from any suitable plastics material such as a thermosetting plastic, for example, polyethylene, polystyrene, polyurethane etc.

The plastics sheet 51 is then fed through a second roller 57 where ink traces 55 are printed on to the sheet 51. The ink traces 55 form a pattern indicating the eventual position of the conductive traces.

The ink may comprise a carrier material to form a seed for the subsequent electroplating of the conductive traces. Examples of suitable carrier materials include palladium or copper.

The ink may also comprise a binder material to ensure good adhesion between the conductive traces and the substrate 15. The ink may also have elastic properties so that it may be stretched during the molding process.

After the ink traces 55 have been printed, the plastics sheet 51 is passed through a molding arrangement 57 where it undergoes vacuum compression molding into the form of the substrate 15.

The substrate 15 then undergoes an electroplating process in which metallic particles are plated to the ink traces 55 to form the conductive traces.

The electroplating process may be a two step process. In the first step the carrier material in the ink traces 55 is activated 59. The carrier material may be activated 59 by, for example, rinsing with acid or irradiation. The second step is the electroplating step in which metal is plated 61 onto the ink traces 55.

Once the conductive traces have been formed an electronics module, such as a display module 13, can be mounted to the molded substrate.

In the above described embodiments the electronics module is a display module 13. Other types of electronics modules could be used for example a camera module or a user interface module.

Furthermore, in the above described embodiments only a single electronics module is mounted on the substrate 15, in other embodiments a plurality of electronics components may be mounted on the same substrate 15.

Although embodiments of the present invention have been described in the preceding paragraphs with reference to various examples, it should be appreciated that modifications to the examples given can be made without departing from the scope of the invention as claimed.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/We claim:

1. An apparatus comprising:
a substrate;
an electronics module mounted on the substrate; and
an injection molded layer in contact with the substrate;
wherein the substrate and the injection molded layer form a portion of a rigid housing.

2. An apparatus as claimed in claim 1 wherein the substrate is curved so as to form a gap between a portion of the electronics module and the substrate.

3. An apparatus as claimed in claim 2 wherein the substrate is provided with a plurality of corrugations.

4-13. (canceled)

14. An apparatus as claimed in claim 1 further comprising a frame mounted on the substrate arranged to protect the electronics module during formation of the injection molded layer.

15. An apparatus as claimed in claim 14 wherein the frame is adhered to the electronics module.

16. An apparatus as claimed in claim 1 wherein the electronics module is a display module.

17. An apparatus as claimed in claim 1 wherein a plurality of electronics components are mounted on the substrate.

18. An apparatus as claimed in claim 1 wherein the injection molded layer forms a portion of the external housing of the apparatus.

19. An apparatus as claimed in claim 18 wherein the external housing comprises a guide structure to facilitate positioning of the electronics component.

20. A method of assembling an apparatus comprising electronic components, the method comprising:
positioning a substrate, supporting an electronics module, between the electronics module and a cavity to operate as a barrier during injection molding;
forming an injection molded layer in contact with the substrate and thereby integrating the injection molded layer and the substrate to form a portion of a rigid housing.

21. A method as claimed in claim 20 wherein the substrate is arranged to be deformable during the injection molding process.

22. A method as claimed in claim 20 wherein a gap is provided between the substrate and the electronics module.

23. A method as claimed in claim 20 wherein a frame is provided to contact with a preformed portion of the rigid housing and provide a seal around the electronics module.
